(19) United States
(12) Patent Application Publication
(10) Pub. No.: US 2022/0389563 A1
(43) Pub. Date: Dec. 8, 2022

(54) SYSTEM FOR FASTENING OPTICAL COMPONENTS

(71) Applicant: SAFRAN ELECTRONICS & DEFENSE, PARIS (FR)

(72) Inventors: Joël FLEURY, BOULOGNE (FR); Maxime PARAILLOUX, BOULOGNE (FR); Cyril DUPEYRAT, BOULOGNE (FR); Michel BIDAUD, BOULOGNE (FR)

(21) Appl. No.: 17/776,782

(22) PCT Filed: Nov. 10, 2020
(86) PCT No.: PCT/FR2020/052052

§ 371 Date: May 13, 2022

(30) Foreign Application Priority Data
Nov. 14, 2019 (FR) FR1912703

(51) Int. Cl. C23C 14/22; C23C 14/54

(52) U.S. Cl. CPC C23C 14/225; C23C 14/547

(57) ABSTRACT

An attachment system and method for optical parts for applying treatments and deposits on at least one surface of said parts without sparse zones on said surface. The system includes an optical part holder in the form of a flange provided with two branches connected at respective first branch ends thereof by a spring link and provided at respective second branch ends thereof with facing tabs and means for bringing said tabs together suited for tightening the branches on an edge of said parts. The method includes a step of positioning an optical part holder in the form of a flange on the edge of said optical part, where a front surface of said flange is positioned recessed from the surface to be treated or flush with the surface to be treated and a step of tightening the flange on the edge of said optical part.

### CROSS-REFERENCE TO RELATED APPLICATIONS

This application is a 35 U.S.C. § 371 filing of International Application No. PCT/FR2020/052052 filed Nov. 10, 2020, which claims the benefit of priority to French Patent Application No. FR1912703 filed Nov. 14, 2019, which is incorporated herein by reference in its entirety.

### FIELD OF THE INVENTION

The present disclosure relates to the field of surface treatments of optical parts and relates in particular to a system for attachment of the optical parts in order to perform the treatments to the surface thereof.

The systems for attachment of optical parts in order for application of surface treatments thereto must avoid comprising parts interfering with the treatment and the surface to be treated. In contrast, in connection with depositing thin layers with the GLAD process (Glancing Angle Deposition) the attachment must consider the effect of significant shadows related to the orientation of the optical parts relative to the direction of the evaporation flow.

### BACKGROUND

The usual configuration for the positioning and attachment of optical parts in the frames for deposition of thin layers consists simply of placing the parts on a support comprising a plane for annular placement on the part. The negative effects of this are to create, on the periphery, during deposition, a sparse zone without treatment and, according to the shape and dimensions of the placement plane, and, in the case of GLAD type deposition, creating an additional shadow area. The necessity of pacing the parts on an annular placement plane leads to the part resting on the frame not being treated. In fact, since the frame is in this case an extra thickness, it partially masks the surface to be treated when the treatment is done with large incidences relative to the surface to be treated, like for example during GLAD type treatment.

The sparse zone created by conventional deposits with optical parts normal to the evaporation flow is in general not critical when the optical parts are finally assembled in barrels and there is no need for contact between the treated surface and the barrel with the support. In other cases, it is necessary to trim the parts after treatment for eliminating the sparse zone. Such trimming is undesirable or even impossible on high-performance optical parts, and therefore high cost, for which the trimming operations are nearly always done before treatment or finishing of the part.

In the case of a deposition by GLAD process, the problem is further heightened because the zones without deposits are more extensive as shown in FIG. 1 which shows a device from the prior art for holding an optical part A with a support B. In the case of depositing thin layers on an optical part A with an evaporation flow 100 according to the GLAD process, the effect of shading D due to the bearing parts C of the support B is unacceptable because it creates inhomogeneous zones which do not allow control of the index of the layers. These zones can be extremely extended depending on the angle of incidence of the flow on the optical parts.

Another problem is that the parts to be treated in general rest on a support which does not allow treating the parts all the way to the edge thereof, which can prove bothersome, since high performance optical parts cannot be reworked by machining after treatment.

In order to avoid the shadowing effect during GLAD deposition, the usual configuration cannot be used. It is imperative that no mechanical element of the support be located in the evaporation path between the source and the surface to be treated.

### BRIEF SUMMARY OF THE INVENTION

The present invention resolves these problems and relates to an attachment system with which to implement deposits without sparse zones and without shadow zones, whatever the experimental conditions (maximal incidence and azimuthal rotation of the optical parts).

The principle of the invention is based on a system of attachment by yoking/clamping of the segment of the optical parts by means of a yoking/clamping device which is applied to the segment or edge of an optical part and which comprises a front surface recessed or possibly flush with a surface to be treated but not extending past this surface to be treated of the part. The attachment system is also a system for holding parts in position in order for treatment thereof.

More precisely, according to a first aspect of the invention, an attachment system for optical parts for applying treatments and deposits on at least one surface of said parts without sparse zones on said surface is proposed which comprises an optical part holder in the form of a flange provided with two facing branches shaped for being applied on two sides of the edge of the optical part, wherein the two facing branches have first and second branch ends, and are connected at their respective first branch ends by a spring link and provided at their respective second branch ends with facing tabs; and means for bringing said facing tabs together and for tightening the branches on the edge of said optical parts.

This simple to implement part holder serves to hold said part while leaving the surface to be treated completely free and without interfering with the surface to be treated of the part.

The characteristics of the system disclosed in the following paragraphs may, optionally, be practiced. They may be practiced independently of each other or in combination with each other.

The part holder is advantageously metal and preferably stainless steel. This material, which provides a good grip on optical parts, perfectly conducts heat and homogenizes the temperature of the treated parts.

The spring link is advantageously U-shaped.

The part holder preferably has a reduced thickness compared to the branches, comprises two segments which extend radially outward from the flange, which are connected to the respective first branch ends of the branches at respective first segment ends thereof, and which are connected at respective second segment ends thereof to a circular arc segment providing the elasticity of the spring link. The spring link with reduced thickness compared to the curved branches is therefore more elastic than the branches and the segments forming the branches of the U may deflect towards each other when the tabs are tightened by the means of bringing closer, which tighten the flange on the optical part.

The means for bringing closer may comprise a screw passing through one of the tabs and engaging with threading of the other of the tabs for tightening said branches on said edge.

The system may comprise a jig for mounting of one or more of said flanges on one or more of said optical parts, constituted of a block provided with an upper surface, in which a groove is cleared provided with a lower surface, surrounded on two opposite sides by convergent walls and which constitutes a plane for placement of optical parts of various diameters in retained position wedged between said walls, where said upper surface forms a reference surface for placement of said flanges on the edge of said optical parts.

The jig serves to equip one or more optical parts of different diameters with the flanges thereof.

The attachment system may comprise one or more annular shims suited to be inserted between the plane of placement and the optical parts with convex surface to be treated.

The system may comprise a support in which one or more optical parts to be treated equipped with a flange are arranged and which comprises a front surface formed by a front surface of a deposition tray pierced by openings through which the surfaces to be treated of said optical parts are entirely accessible. To do that, the optical parts are advantageously positioned in the flanges thereof and mounted on the deposition tray so as to be flush with the front surface of the deposition tray. In this case, the flange will be mounted recessed from the surface to be treated of the optical part in order to compensate at least for the thickness of the tray under the flanges.

It should be noted that the support can be used with a yoking/clamping device made up of a flange provided with two branches connected at respective first branch ends thereof by a spring link and provided at respective second branch ends thereof with facing tabs and means for bringing said tabs together, however a clamping device such as the flange equipped with a different tightening means or spring device may be used with this support.

The attachment system may comprise a rear cover provided with a means of attachment of the support onto a handling module.

Said cover may comprise a peripheral wall suited for housing the optical parts and the flanges thereof between the cover and the deposition tray.

Advantageously, a front surface of the flanges is received in depressions on a rear surface of the deposition tray whereas the counter plate housed in the support and fixed to the rear of the tray comprises an annular crown bearing on a rear surface of the flanges from the side opposite to the side to be treated of the optical parts and a rear wall facing the rear surfaces of the optical parts protecting said rear surface so as to avoid parasitic deposits on said rear surface.

The cover and the deposition tray are secured together by screws such as knurled screws passing through the cover and screwing into first threaded holes of the deposition tray.

The present application further proposes a method for attachment of one or more optical parts for the preparation thereof in order for a method for depositing on at least one optical surface to be treated of said part which comprises a step of positioning an optical part holder in the form of a flange according to the present application on the edge of said optical part, where a front surface of said flange is positioned recessed from the surface to be treated or flush with the surface to be treated and a step of tightening the flange on the edge of the optical part.

The characteristics of the method disclosed in the following paragraphs may, optionally, be practiced. They may be practiced independently of each other or in combination with each other.

Prior to the positioning and tightening of the flange on the optical part, the method may comprise a step of bringing and wedging the optical part between the walls of a jig according to the application by sliding of the part, supported or not by an annular shim according to whether the surface to be treated of the part is convex or not, on a placement plane of the jig, where the positioning and tightening steps of the optical part holder on the optical part are done with the part wedged between said wall and flange bearing on the upper surface of the jig and followed by a step of removing the jig from the part equipped with the flange thereof.

In that way the flange tightened on the edge of the optical part is precisely positioned relative to the surface to be treated of the optical part.

Similarly, the optical parts may be positioned in the flanges thereof by the jig so as to make the front surface of a deposition tray flush once mounted with their flanges on this deposition tray.

According to an important aspect of the invention the method may comprise for one or more optical parts:

the placement of said parts equipped with the flanges thereof on a deposition tray with openings through which the surfaces to be treated of said optical parts are accessible, where the front surface of the flanges is received in depressions in the rear surface of the deposition tray;

the attachment of a counter plate to the rear of said tray pressing said optical parts against said rear surface, where the counter plate comprises for each of said optical parts an annular crown bearing on a rear surface of the flanges from the side opposite to the side to be treated of the optical parts;

the attachment of the tray assembly, flanged optical parts and counter plate in a cover of a support, where said cover comprises a peripheral wall suited to house the counter plate, the optical parts and the flanges thereof between a rear surface of the cover and the deposition tray.

The method may further comprise the attachment of the support onto a handling module of a deposition machine.

The device and the method from the invention thus serve to assure an optimal hold of the optical parts on a deposition machine comprising means for movement of the supports in particular according to azimuthal rotations, for assuring the alignment of the optical part in the support thereof, for depositing over 100% of the treated surface and for avoiding a shadow effect.

Further, the device and method from the present application serve to perform deposits on both surfaces of optical parts, one after the other.

### BRIEF DESCRIPTION OF THE DRAWINGS

Other features, details and advantages of the invention will appear upon reading the following detailed description and analyzing the attached drawings, on which:

FIG. 1 shows a schematic view of a part of a support device from the prior art;

FIG. 2 shows a schematic view of a principle of the invention;

FIG. 3 shows in perspective a flange device from the invention;

FIG. 4A, FIG. 4B show in perspective and in exploded view a first embodiment of a support for mounting devices from FIG. 1 on optical parts;

FIG. 5A, FIG. 5B show in perspective and in exploded view a second embodiment of a support for mounting devices from FIG. 1 on optical parts;

FIG. 6A, FIG. 6B show in perspective from top and bottom a support for optical parts for deposition.

FIG. 7 is an exploded view of the support from FIGS. 6A, 6B.

### DETAILED DESCRIPTION OF THE INVENTION

The following drawings and description contain, for the most part, elements of definite nature. They could therefore not only serve to better understand the present invention, but also contribute to the definition thereof, as needed.

Now referring to FIG. 2.

According to FIG. 2, the principle of the invention is to use a yoking/clamping device 10 which is applied onto the segment or edge 2 of an optical part 1 to be treated by a deposition process such as a GLAD process.

The device 10 comprises a front surface 16 that is recessed or flush but does not go past the surface to be treated 3 of the part. In that way, no obstacle disturbs the deposition by a vapor flow 100.

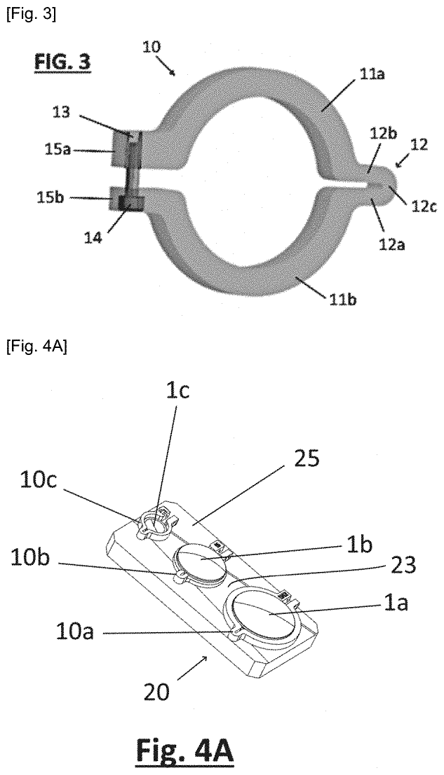

According to FIG. 3, the part holder 10 is made up of a spring effect flange.

According to the example, the flange is provided with two branches 11a, 11b, intended to tighten around the edge of the optical parts. These branches are connected at respective first branch ends of the branches thereof by a spring link 12.

The U-shaped spring link comprises two segments 12a, 12b whose respective first segment ends are radially connected to the branches and whose respective second segment ends are connected to a circular arc segment 12c that gives elasticity to the spring link. The thickness of the spring link is reduced compared to the branches in order to deflect more easily than them.

At respective second branch ends thereof opposite the spring link, the branches each comprise a tab 15a, 15b radially outward from a contour formed by the branches. The flange is provided with complementary means of tightening 13, 14 which are, in the example shown, made with a screw 14 passing through a hole of the tab 15b and screwing into a threaded hole 13 of the tab 15a. These means of tightening may also be another type, for example, a notched pawl coming from one of the tabs and which latches with complementary notches made on the other tab.

The flanges are adapted in thickness relative to the optical parts to be treated and in particular the thickness of the flange may be chosen less than the thickness of the lens, similarly the shape and length of the branches of the flange are adapted to the lens to be held. They are made of metal and preferably of stainless steel.

According to the example shown, the optical parts or circular lenses and the branches are curved and match the edge of the lenses. Optical parts can also be oval or polygonal, and the branches are then adapted to the contour of said parts.

The essential characteristics of the part holder are to be easily positionable on the edge of the optical part, to hold the optical part firmly once tightened on the optical part, and to have a stiffness in the axial direction sufficient for not being crushed when the part holder is fixed in a support for treatment of the optical part, and to make grasping of the part easier without touching it.

The implementation of the flange in stainless steel, beyond the low cost thereof, allows multiple cycles of tightening and loosening, allows heating of the optical parts as needed because the stainless steel is a good thermal conductor, and allows easy cleaning of the flange.

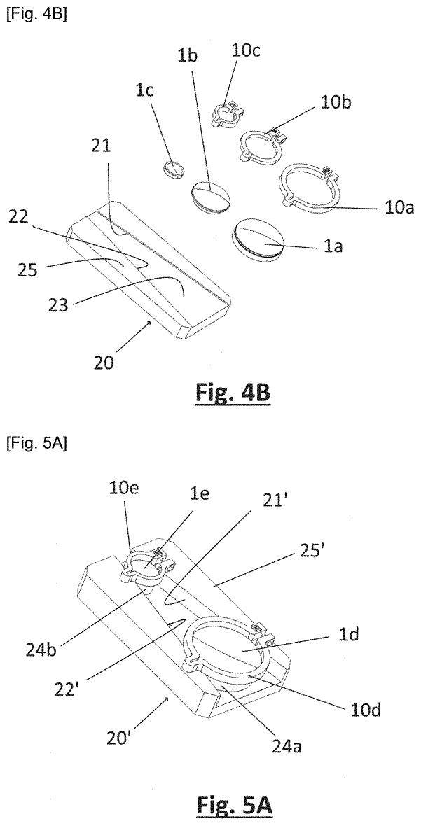

FIGS. 4A and 4B show the first embodiment of a device for placement of flanges on circular optical parts. This embodiment is suited to optical parts such as lenses comprising a concave or flat surface to be treated. The placement device comprises a jig 20 made up of a block provided with an upper surface 25 in which a groove is cut out provided with a lower surface 23 surrounded on two opposite sides by convergent walls referenced 21, 22 in FIG. 4B. The groove in that way has a decreasing width which forms a plane for placement with which to bring, by sliding on the placement plane, lenses 1a, 1b, 1c of various diameters in retained position wedged between the walls to equip them with the flange 10a, 10b, 10c that corresponds to the diameter thereof.

It should be noted that the invention may be applied to optical parts such as lenses or adhered optical doublets.

The height of the walls 21, 22 of the groove is calibrated such that the flanges 10a, 10b, 10e placed on the upper surface 25 of the jig are at a fixed distance from the surface to be treated of the lenses which is positioned on the placement plane.

The placement plane 23 and the walls 21, 22 are preferably covered with an anti-scratch material such as PTFE.

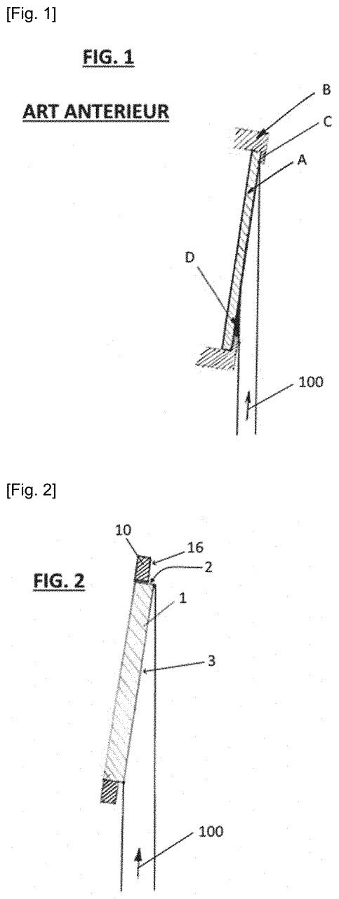

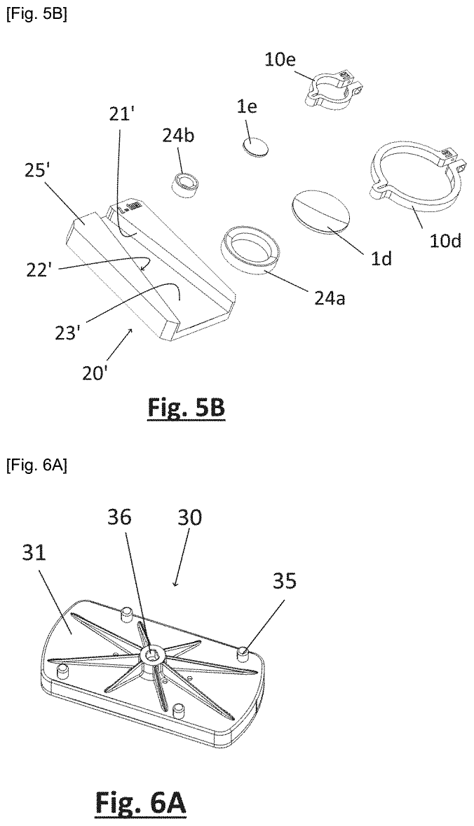

FIGS. 5A and 5B correspond to a second embodiment of the device for placement of flanges on optical parts. This embodiment is this time suited to optical parts such as lenses 1d, 1e comprising a convex surface to be treated. There again, the placement device comprises a jig 20′ provided with an upper surface 25′ and a groove of decreasing width defining a surface 23′ surrounded on two opposite sides by convergent walls 21′, 22′ in order to form a plane for placement of the optical parts. In contrast, as the surface of the lenses 1d, 1e is convex, it is not possible to slide them directly on the placement plane in order to wedge them between the walls 21′, 22′. Also, the device further comprises, in this case, annular shims 24a, 24b, on which the edge of the surface to be treated of the lenses is placed. These lenses placed on the annular shims thereof are brought by sliding on the placement plane into retained position between the walls in order to equip them with the flange 10d, 10e corresponding to the diameter thereof. The annular shims serve to compensate for the curvature of the convex lens in order to adjust the relative height between the surface 3 of the lens and the front surface 16 of the flange 10 shown in FIG. 1.

In this embodiment, the annular shims 24a, 24b, like the placement plane of the jig, are covered with an anti-scratch material.

The height of the walls 21′, 22′ is here selected in order to compensate for the height of the shims 24a, 24b such that when the flanges rest on the upper surface 25′ of the jig, they can retain the optical parts without going past the side of the convex surface thereof to be treated.

In the examples from FIGS. 4A and 4B, three lenses 1a, 1b, 1c are shown and in the examples from FIGS. 5A and 5B two lenses 1d, 1e are shown. It is thus possible to make longer or shorter jigs in order to receive one or more lenses for flanges.

The method for equipping the optical parts with the flange thereof comprises wedging the optical parts by sliding the parts or sliding the shims carrying the parts on the surface of the placement plane between the walls of the placement plane until the parts are wedged between the walls and then the sliding of the flanges around the optical parts until the flanges rest on an upper wall of the jig and then tightening the tightening means of the flanges onto the edge of the optical parts.

Positioning the flanges according to the thickness of the optical parts is thus done by means of jigs that are specifically machined and comprise a PTFE coating in order to avoid scratching during placement of the flanges and tightening of the flanges onto the optical parts. Different widths and different depths of cutting of the grooves of these jigs allow selecting a jig suited for any optical part.

The system from the present application for attachment of optical parts allows deposition of thin layers on optical parts over the entirety of their surface, on both surfaces, for all possible angles of incidence without sparse zones and without shadow zones.

This system, designed for not scratching the optical parts during handling thereof, can be used for many shapes of flat plates, concave and convex lenses, filters, mirrors or the like and may be easily adapted to any type of machine for deposition of thin layers.

A simple screwing of the spring effect flange allows a reliable attachment for deposition up to 200° C.

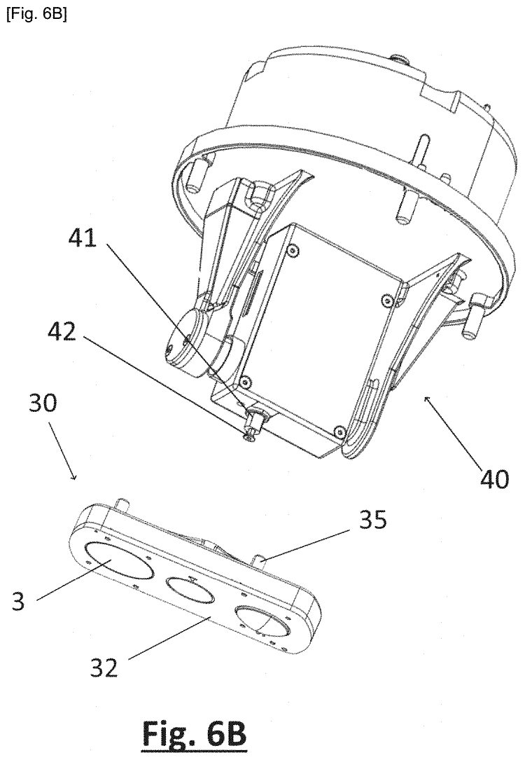

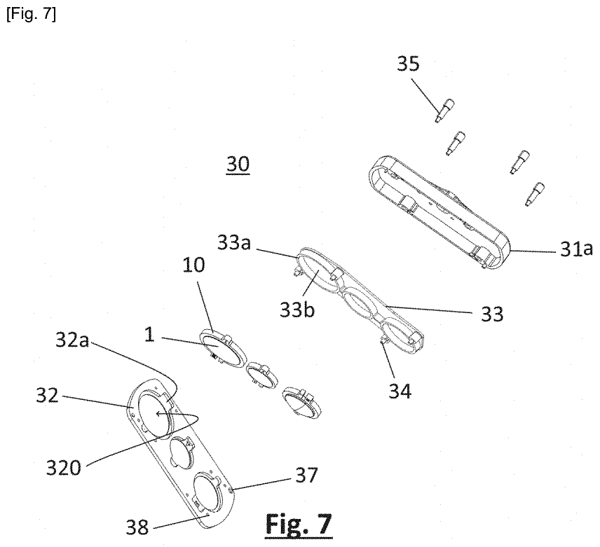

FIGS. 6A, 6B and 7 show an example of a support 30 for optical parts for the treatment of these parts.

This support is therefore defined for holding optical parts equipped with yoking/clamping devices which are applied to the segment or the edge of the optical parts and which comprise a front surface recessed or flush but not extending past a surface to be treated of the parts.

According to this example, the support is rectangular and receives three optical parts with different diameters.

The support 30 in FIGS. 6A and 6B comprises a rear cover 31 provided with a means 36 for attachment to a module 40 for handling and maneuvering the support for a deposition machine. The attachment means 36 may be a hole with keyway which receives an axis 41 of the module, a screw 42 screwing into an axial threading of the axle 41 from inside the cover 31 for retaining the axle in the hole 36. Alternatively, the hole 36 may be a threaded hole which receives a threaded axle of the module. According to FIG. 7, which shows the support 30 in exploded view, the support in which the optical parts 1 to be treated are arranged comprises a front surface with openings 320 therethrough by which the surfaces to be treated 3 of the optical parts are accessible. This front surface is formed by a deposition tray 32.

The cover 31 comprises a peripheral wall 31a with which to house the optical parts 1 and the flange 10 thereof and also a counter plate 33 between the cover 31 and the deposition tray 32. The cover 31 and the deposition tray are secured together by screws 35 such as knurled screws passing through the cover 31 and screwing into the first threaded holes 37 of the deposition tray 32, where these screws allow easy assembly of the deposition tray and the cover while the deposition tray stays equipped with optical parts and the counter plate.

The rear surface of the deposition tray comprises depressions 32a reproducing the contour of the flanges and the front of the flanges is received in these depressions 32a. In order to see the depressions, the deposition tray is shown along a different angle than the other parts in FIG. 7. The depressions hold the flanges laterally which prevents them from moving in the plane of the deposition tray.

When the flanges are mounted recessed from the optical surface to be treated of the optical parts, the surface to be treated of these latter is received in the openings of the front surface so as to be flush with the front surface of the deposition tray which allows treating the entirety of the optical surface.

The counter plate 33 comes to apply on the rear surface of the optical parts. This counter plate comprises, for each optical part, an annular crown 33a which comes to apply on the flanges from the side opposite to the side to be treated of the optical parts. The counter plate is fixed on the rear of the deposition tray here by means of screws 34 received in second threaded-holes 38 of the deposition tray.

The deposition tray is preferably made of stainless steel like the flanges.

According to the example, the depressions are suited for receiving flanges provided with two curved branches 11a, 11b intended to be tightened around the edge of the optical parts, connected at respective first branch ends thereof by a spring link 12 and each comprising at respective second branch ends thereof a tab 15a, 15b with complementary tightening means 13, 14 such as defined above. The depressions may however in the context of the present application be conformed for receiving part holders for which the spring means and the tightening means are configured differently, for example a flange whose curved branches could be connected at each of the ends thereof by a spring link or comprising a tightening means at each of the ends thereof.

The counter plate further comprises a rear wall 33b protecting the rear of the optical parts and avoiding parasitic deposits on the rear surface of the optical parts 1.

The use of a “spring effect” flange and also the method of positioning and tightening of the optical parts in such a flange from the present application serves to make a complete and easy-to-use system for the attachment of optical parts of variable diameters (10 mm to 140 mm typically) and variable thickness for depositions of thin layers without sparse zones allowing a treatment over 100% of the area of the optical surfaces of the parts and suited to deposition with the GLAD process.

The materials selected for the flanges and the elements of the support are suited for doing depositions in a temperature range extended from 20° C. to 200° C.

For example, to get a good hold of the optical parts, the flanges are stainless steel. This material conducts heat perfectly and homogenizes the temperature of the parts to be treated.

Similarly, for homogenizing the temperature of the treated parts, the deposition tray is advantageously also stainless steel.

The counter plate is made of a polymer or a resin suited for resisting temperatures of order 200° C. and for example of a material usable in stereolithography known under the brand PerFORM or of PEEK.

The rear cover 31 may advantageously be made of PEEK in order to support 200° C. without deformation.

Other than the case of GLAD treatment, the invention applies to optical parts treated when one wants the treatment of the optical part to extend out to the edge thereof like for example for a viewing window provided with a conducting treatment which must be in electrical contact with the support of the part.

The invention is not limited to the example shown and in particular the support 30 may also be round or oval and receive a different number of optical parts, for example depending on the surface of the support and the diameter of said parts.

1. An attachment system for optical parts for applying treatments and deposits on at least one surface of said parts without sparse zones on said surface characterized in that it comprises:
an optical part holder in the form of a flange provided with two facing branches shaped for being applied on two sides of the edge of the optical part,
wherein the two facing branches have first and second branch ends, and are connected at respective first of the branch ends by a spring link and provided at respective second branch ends with facing tabs; and
means for bringing said facing tabs together and for tightening the branches on the edge of said optical parts.

2. The attachment system for optical parts according to claim 1 wherein the spring link, U-shaped and having a reduced thickness compared to the branches, comprises:
two segments which extend radially outward from the flange, which are connected to the respective first branch ends of the branches at respective first segment ends thereof, and which are connected at respective second of segment ends thereof to a circular arc segment providing the elasticity of the spring link.

3. The attachment system according to claim 1 wherein the means for bringing closer comprises a screw passing through one of the facing tabs and engaging with threading of the other of the facing tabs for tightening said branches on said edge.

4. The attachment system according to claim 1 wherein the part holder is stainless steel.

5. The attachment system according to claim 1 comprising a jig for mounting of one or more of said flanges on one or more of said optical parts, constituted of a block provided with an upper surface, in which a groove is cleared provided with a lower surface, surrounded on two opposite sides by convergent walls and which constitutes a plane for placement of optical parts of various diameters in retained position wedged between said walls, where said upper surface forms a reference surface for placement of said flanges on the edge of said optical parts.

6. The attachment system according to claim 5 comprising one or more annular shims suited to be inserted between the plane of placement and the optical parts with convex surface to be treated.

7. The attachment system according claim 1 comprising a support in which one or more optical parts to be treated equipped with the flange thereof are arranged and which comprises a front surface formed by a front surface of a deposition tray pierced by openings through which the surfaces to be treated of said optical parts are entirely accessible.

8. The attachment system according to claim 7 comprising a rear cover provided with a means of attachment of the support onto a handling module.

9. The attachment system according to claim 8 wherein said rear cover may comprise a peripheral wall suited for housing the optical parts and the flanges thereof between the rear cover and the deposition tray.

10. The attachment system according to claim 9 wherein a front surface of the flanges is received in depressions on a rear surface of the deposition tray whereas the counter-plate housed in the support and fixed to the rear of the tray comprises an annular crown bearing on a rear surface of the flanges from the side opposite to the side to be treated of the optical parts and a rear wall facing the rear surfaces of the optical parts and protecting said rear surface so as to avoid parasitic deposits on said rear surface.

11. The attachment system according to claim 8, wherein the cover and the deposition tray of the support are secured together by screws such as knurled screws passing through the cover and screwing into first threaded holes of the deposition tray.

12. A method for attachment of one or more optical parts by means of the attachment system according to claim 1 for depositing on at least one optical surface to be treated of said part, the method comprising:
positioning the optical part holder in the form of a flange on the edge of said optical part, where a front surface of said flange is positioned recessed from the surface to be treated or flush with the surface to be treated; and
tightening the flange on the edge of said optical part.

13. The method for attachment of one or more optical parts according to claim 12, wherein the attachment system further comprises a jig for mounting of one or more of said flanges on one or more of said optical parts, constituted of a block provided with an upper surface, in which a groove is cleared provided with a lower surface, surrounded on two opposite sides by convergent walls and which constitutes a plane for placement of optical parts of various diameters in retained position wedged between said walls, where said upper surface forms a reference surface for placement of said flanges on the edge of said optical parts, the method comprising
prior to positioning and tightening of the flange on the optical part, a bringing and wedging the optical part between the walls the jig by sliding of the part, supported or not by an annular shim according to whether the surface to be treated of the part is convex or not, on a placement plane of the jig;
wherein positioning and tightening of the optical part holder on the optical part are done with the part wedged between said wall and flange bearing on the upper surface of the jig and followed by removing the jig from the part equipped with the flange thereof.

14. The method for attachment of one or more optical parts according to claim 12 comprising:
the placement of said optical parts equipped with the flanges thereof on the deposition tray with openings through which the surfaces to be treated of said optical parts are accessible, where the front surface of the flanges is received in depressions in the rear surface of the deposition tray;
the attachment of a counter plate to the rear of said tray pressing said optical parts against said rear surface, where the counter plate comprises for each optical part an annular crown bearing on a rear surface of the flanges from the side opposite to the side to be treated of the optical parts;
the attachment of the tray assembly, flanged optical parts and counter plate in a cover of a support, where said cover comprises a peripheral wall suited to house the counter plate, the optical parts and the flanges thereof between a rear surface of the cover and the deposition tray.

15. The method for attachment of one or more optical parts according to claim 14 comprising the attachment of the support to a module for handling and maneuvering the support.
